(19) United States
(12) Patent Application Publication
(10) Pub. No.: US 2015/0259819 A1
(43) Pub. Date: Sep. 17, 2015

(54) Asteriated Substrate for Light Emitting Diodes

(71) Applicant: Eric Colin Bretschneider, Bowling Green, KY (US)

(72) Inventor: Eric Colin Bretschneider, Bowling Green, KY (US)

(21) Appl. No.: 14/212,862

(22) Filed: Mar. 14, 2014

(51) Int. Cl. C30B 1/04; C30B 29/16; C30B 33/02; C30B 29/20

(52) U.S. Cl. CPC C30B 1/04; C30B 29/20; C30B 29/16; C30B 33/02

(57) ABSTRACT

Optical extraction efficiencies for GaN based light emitting diodes may be improved by forming titanium dioxide inclusions in a sapphire based substrate. These inclusions increase optical scattering of light that has been injected into the sapphire, thereby improving overall performance of the light emitting diode. A portion of the titanium dioxide inclusions may extend to one or more surfaces of the sapphire. Selective etching may be performed on the surface of the sapphire prior to epitaxial growth of the GaN based light emitting diode. This allows formation of a textured sapphire surface in a single process step without the use of photolithography. This process step as well as additional selective etching of exposed titanium dioxide on other surfaces of sapphire may be performed to further increase LED performance.

### RELATED APPLICATION

This application claims the benefit of priority from U.S. Application No. 61/785,897 filed on Mar. 15, 2013, the contents of which are hereby incorporated by reference as if fully set forth herein.

### TECHNICAL OF THE INVENTION

GaN based light emitting diode (LED) structures are commonly grown on sapphire substrates. The growth methods and techniques are well known and such devices have been commercially available since the early 1990's. Sapphire is highly transparent to visible light and is able to withstand the harsh growth conditions required to growth GaN based materials.

Despite its high transparency, sapphire is not an ideal substrate in terms of optical device formation. Light produced inside a GaN based LED is emitted in all directions. Due to the high refractive index of GaN based materials, a large portion of this light is trapped within the structure. The ability of light to be transmitted across an interface depends on the angle of incidence and the difference in refractive index between the two materials on either side of the interface.

Early GaN based LEDs used sapphire substrates with a very smooth surface. This surface greatly limited light extraction in the finished LED structure. Since LEDs are planar structures, light the reflects from one interface without changing the angle of incidence can continue reflecting between the top and bottom layers of the LED structure until it encounters an edge. At the edge, the light may still be trapped depending on the angle of incidence.

In order to improve the optical performance, patterned sapphire substrates have been developed. These patterned sapphire substrates change the interface between the GaN material and the sapphire so that it is no longer a smooth interface. The interface of a patterned sapphire substrate presents a wide variety of angles so that light that is not transmitted through the interface changes its angle of incidence to the upper surface of the LED structure. This greatly reduces internal reflection and thus improves the optical performance of LEDs.

Patterned sapphire substrates are formed using multiple process steps that include: applying a mask material, patterning the mask material using a photolithographic process, applying an etching process on the exposed sapphire not covered by the mask material and removal of the mask.

This process for forming patterned sapphire substrates is typically conducted in a semiconductor fabrication facility. A clean room environment is necessary for the process which greatly adds to the cost of the substrates. Substrates must also be processed through the photolithography process sequentially which adds to the process time and hence also increases cost.

Sapphire substrates have another inherent limitation when growing GaN materials in that there is a poor lattice match between sapphire and GaN. This mismatch results in a high density of dislocations. Numerous growth techniques such as the use of buffer layers have been developed over the years to reduce the dislocation density of GaN materials grown on sapphire substrates. If growth is initiated on the highest points of a patterned sapphire substrate, then subsequent growth may proceed in free space and be freed from the constraints of the sapphire substrate. The material grown over the low lying portions of a patterned sapphire substrate will thus have a reduced dislocation density. These low dislocation density regions coalesce and film growth proceeds.

Recently it has been shown that scattering zones in the sapphire substrate of a GaN based LED improve the optical performance of LED devices. These scattering zones are formed by a laser process as detailed in abandoned US patent application 2010/0102352. This laser process is only able to form scattering centers in very limited regions. Thus the laser must be scanned or rastered across the sapphire substrate to complete formation of the scattering layer. The physical properties of sapphire including its high optical transparency, high melting temperature and extreme hardness means that this process requires a very high intensity laser to create scattering zones in the sapphire. This further increases the processing cost of this method.

Other researchers, notably Zhang, et al, “Improved Light Output from InGaN LEDs by Laser-Induced Dumbell-Like Air-Voids”, Optics Express, vol 21, No. 26, pp 32582-32588 (2013) have developed similar processes based on forming scattering centers in sapphire substrates subsequently used for growth of GaN based LEDs. These studies have found net improvements in light output of up to 24.7% compared to use of traditional sapphire substrates.

Residual damage to the sapphire material in the vicinity of the voids created by the laser prevents formation of an additional layer of scattering centers. This limits the ability of the technique to enhance light extraction from the sapphire. Further improvements should be possible if scattering centers could be produced in a three dimensional volume.

Another limitation inherent to these types of laser based processing steps is that they require precise focusing of a high intensity beam of laser light through the surface of the sapphire substrate to a region below the surface. In order to control the formation of scattering zones without damaging the surface, the surface of the substrate must be extremely smooth and optically flat. If the surface is not optically flat then the high intensity beam of laser light will be distorted and it may be impossible to form the scattering zones.

Further the formation of scattering centers by a laser process requires use of an expensive high power industrial laser. Additionally the laser focus must be carefully maintained at the same depth inside the sapphire substrate as it is rastered across the substrate. Substrates must also be processed one at a time through the laser system. This results in a time consuming and hence expensive process.

Bulk growth of sapphire is well known in the art. It is grown in commercial quantities by a number of techniques including but not limited to Czochralski, Kyropoulos, Edge Film Growth and Heat Exchanger method. Sapphire is a crystalline form of aluminum oxide. In its pure state sapphire is highly transparent over a very wide range of wavelengths and is without color. Some metal oxides have a very high solubility in sapphire and may result in the formation of color centers in sapphire even in low concentrations. For example chromium oxide in sapphire results in a pink or red color depending on the amount of chromium oxide present. High concentrations of chromium oxide in sapphire are responsible for the red color of rubies. In a similar manner, high concentrations of titanium dioxide in sapphire are responsible for the deep blue color of blue sapphire gemstones. In this disclosure, the term sapphire is used to refer to any crystalline material composed primarily of aluminum oxide regardless of its color. Ruby is a specific form of sapphire with high amounts of chromium oxide that has a distinct red color.

The concentration of metal oxides in sapphire is not sufficient by itself to determine the color of the resulting sapphire. The thermal history of the material affects the final color an appearance of the sapphire material. Heat treatment of sapphire gemstones is well known. Various processes have been developed over the years to improve and modify the appearance of sapphire gemstones by heating them to a predetermined temperature for a specified amount of time in a controlled atmosphere. Commonly these treatments are used to improve the clarity or transparency of gemstones.

Titanium dioxide may exist in sapphire as a solid solution. In some cases a second solid phase of titanium dioxide may be present depending on the crystal growth conditions and thermal history of the ruby or sapphire. Initially transparent sapphire may be subject to thermal processing in order to cause the precipitation of titanium dioxide as a second solid phase in a matrix of aluminum oxide. The precipitated titanium dioxide typically takes the form of needle like inclusions of rutile with hexagonal symmetry around the c-axis of sapphire. These types of titanium dioxide inclusions are responsible for the asterism in star rubies and sapphires. It is noted here that rutile is one of the crystalline forms of titanium dioxide.

Titanium dioxide may be introduced into sapphire while it is in a molten state. Depending on the temperature profiles of the sapphire as it crystallizes and cools to near room temperature the titanium dioxide may remain in a solid solution or crystallize. Careful control of the cooling rate of sapphire with dissolved titanium dioxide may thus result in the formation of bulk sapphire with titanium dioxide inclusions.

A solid solution of sapphire and titanium dioxide may be subject to additional thermal processing to induce crystallization of the titanium dioxide as outlined in U.S. Pat. No. 2,488,507 the contents of which are incorporated herein by reference. Thus it is possible to subject sapphire substrates with dissolved titanium dioxide to thermal processing to induce formation of titanium dioxide inclusions. These inclusions of titanium dioxide are the rutile crystalline form. This process is commonly used to induce asterism in both natural and synthetic sapphire. Asterated sapphire is also known as star sapphire.

It is also known in the art that asterism in sapphire materials may be induced by applying a titanium compound and subjecting it to thermal processing in a controlled atmosphere as outlined in U.S. Pat. No. 2,690,630 the contents of which are incorporated herein by reference. Thus it is possible to induce asterism in bulk sapphire materials with little or no titanium dioxide.

The optical properties of sapphire and rutile are very different. The refractive index for visible light in sapphire ranges from about 1.75 to 1.77. Rutile has one of the highest refractive indices of any material known for visible light and ranges from about 2.54 to 2.85. This large difference in refractive indices means that optical scattering by rutile inclusions in sapphire is very efficient.

Use of patterned sapphire substrates are known to improve the efficiency of GaN LEDs as outlined in U.S. Pat. No. 7,781,790, the contents of which are incorporated herein by reference. According to the patent at least one mask material is deposited on a sapphire substrate. This mask material is then coated with a mask material which is patterned using a photolithography process. The mask material is then etched using techniques known in the art that are suitable for etching the selected mask material.

Once the patterned mask is formed, the sapphire substrate is then etched using a dry etching process based on plasma chemistries known in the art. After the sapphire etching step, the remaining mask material is then removed using another etching process that does not affect the sapphire.

This process requires at least five different process steps: mask material deposition, photolithography, mask etching, sapphire etching and mask removal. In some embodiments two different mask materials are used and thus result in a process that requires more process steps, longer total process time, higher cost and lower yield.

In particular the extremely low chemical reactivity of sapphire necessitates use of a dry or plasma based etch process. These processes require substrates to be placed on a flat susceptor and transferred into a plasma chamber. Inside the plasma chamber electric and magnetic fields are used to produce a plasma above the substrates which in turn etches the exposed sapphire. Careful control of the process parameters is required to produce a uniform etch rate across the entire susceptor. This limits the amount of material that can be etched in a single process step.

Epitaxial lateral overgrowth is a method known to reduce the dislocation density in epitaxial films. This process can be particularly advantageous in heteroepitaxial growth in highly mismatched material systems such as GaN materials on sapphire as disclosed in U.S. Pat. No. 6,051,849 and U.S. Pat. No. 6,478,871 the contents of which are incorporated herein by reference.

U.S. Pat. No. 6,051,849 teaches growth of a first GaN layer on a sapphire substrate by methods known in the art. Growth is terminated an a layer of a mask material is deposited on the first growth layer. This mask material is patterned using a photolithographic process followed by an etch process. After the etch process the remaining photolithography material is stripped. The wafer is then cleaned resulting in a substrate with a first GaN layer with a patterned mask covering portions of the first GaN layer. The wafer is then returned to the GaN deposition system and epitaxial growth is resumed. The second layer of GaN materials deposits on the exposed first layer. Growth proceeds vertically until the GaN layer reaches the top level of the mask material. At this point the GaN material may grow in a lateral direction over the mask material.

Since the growth in the lateral direction over the mask material is not dependent on the lattice parameter of the mask material, this overgrowth material is substantially free of dislocations. As a result the GaN material above the mask layer has a greatly reduced concentration of dislocation defects.

U.S. Pat. No. 6,478,871 teaches deposition and patterning of a mask material directly on the substrate prior to any growth. Epitaxial growth of GaN materials begins with a buffer layer that preferentially nucleates on the substrate material exposed through the openings of the mask material. After the buffer layer begins to grow laterally over the mask material, growth of the primary layer of GaN material begins.

Again in this process the lateral growth of GaN material occurs without significant interaction with the atomic lattice of the mask material. This greatly reduces the dislocation density of the resulting GaN material.

Both of these outlined processes require multiple processing steps that add significant processing time and potentially significant increases in production cost.

### DEFINITIONS

Asteriated: The term “asteriation” is used herein to refer to a crystal with linear inclusions aligned along crystallographic directions inside the crystal. The linear inclusions may be aligned with one or more crystallographic planes inside the crystal.

GaN/gallium nitride: The terms “GaN” and gallium nitride are used herein to refer to any generic group III nitride compound semiconductor material. This includes GaN, InN, AlN and their alloys (InₓGa₁₋ₓN, AlₓGa₁₋ₓN, InₓAl₁₋ₓN and InₓGa_{y}Al_{1-x-y}N) and includes these materials with or without dopants.

Rutile: The term “rutile” is used herein to refer to a tetragonal crystalline form of titanium dioxide with a nominal composition of TiO₂.

Sapphire: The term “sapphire” is used herein to refer to a crystalline form of aluminum oxide with a nominal composition of Al₂O₃. The term here may also refer to aluminum oxide compositions that may include some amounts of other metal oxides and material that may or may not have a noticeable body color.

Titanium containing material: The term “titanium containing material” is used herein to refer to any material compound containing titanium. This includes chemical compounds such as titanium dioxide whether in powdered or solid form, metallic titanium, wet or dry mixtures that include at titanium dioxide or titanium metal.

Titanium dioxide: The term “titanium dioxide” is used herein to refer to TiO₂. It may refer in some cases to a crystalline form of titanium dioxide or to titanium dioxide in a solid solution with aluminum oxide or sapphire.

### BRIEF DESCRIPTION OF THE DRAWINGS

The described embodiments will be readily understood by the following detailed description in conjunction with the accompanying drawings, and in which:

FIG. 1 illustrates a representative prior art process for forming scattering inclusions in a sapphire substrate using a laser system.

FIG. 2 is a representative process flow diagram of a prior art method of forming a patterned sapphire substrate.

FIG. 3 is a representative process flow diagram for methods for forming an asteriated sapphire substrate.

FIG. 4 is a representative process flow diagram for a method for forming a sapphire substrate with a buried asteriated layer.

FIG. 5 is a representative process flow diagram for a method for forming a sapphire substrate with a pattern of asteriation.

FIGS. 6A, 6B show representative plan views of an asteriated sapphire substrate and a patterned asteriated sapphire substrate respectively.

FIGS. 7A, 7B show representative cross sectional views of a sapphire substrate with an asteriated layer and a sapphire substrate with a buried asteriated layer respectively.

FIG. 8 shows a representative isometric view of a patterned sapphire substrate of the present invention.

### DETAILED DESCRIPTION OF THE DRAWINGS

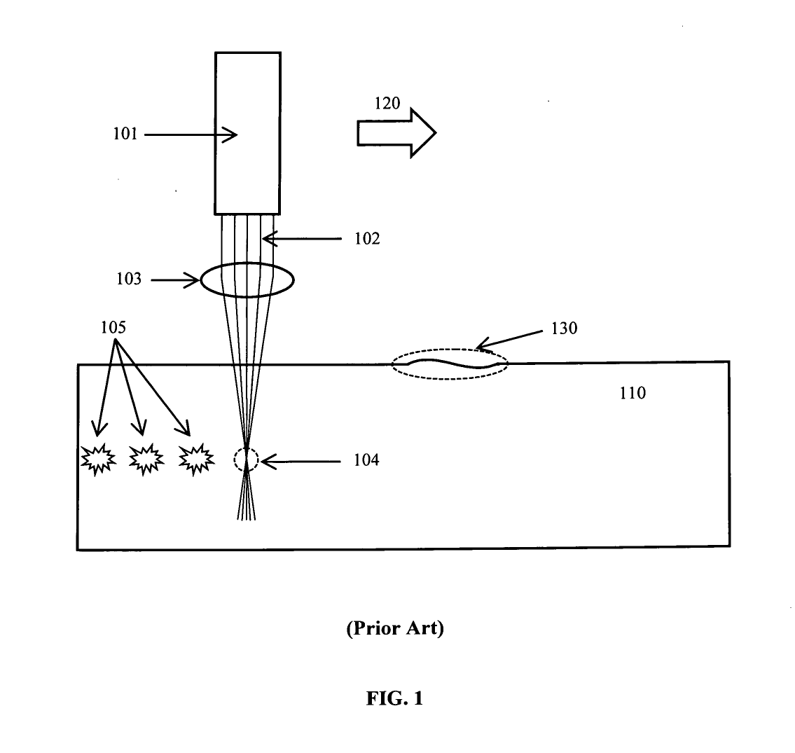

A prior art method of forming optical scattering centers in sapphire substrates is represented diagrammatically in FIG. 1. A high power laser 101 emits a beam of light 102 that is brought into focus at a region 104 inside the body of a sapphire substrate 110. The operating wavelength of the high power laser 101 is chosen to be a wavelength that is minimally absorbed by sapphire. By using a pulsed laser 101 and a precision optical system 103 it is possible to increase the energy density of the beam by several orders of magnitude. In doing so enough energy from the laser beam 102 is absorbed inside the focal region 104 to shock heat the sapphire and result in the formation of a scattering center 105. It may take several beam pulses to fully form a scattering center 105.

Once a scattering center 105 is formed, the entire laser 101 and optical focusing system 103 are moved in a specified direction 120 relative to the sapphire substrate 101 and the process is repeated. This is noted to be a sequential process and only a single scattering center is formed at a time. This results in a long process time to introduce scattering centers 105 across all portions of a wafer. The requirements for a high peak power in the laser 101 as well as a precision optical system 103 required to focus the laser beam 102 into a focal region 104 capable of forming an optical scattering center 105 also results in a high capital equipment cost.

The optical requirements to focus the laser beam 102 into a small focal region 104 also make the process sensitive to the surface quality of the sapphire substrate 110. Imperfections 130 in the surface of the sapphire may change the depth of the focal region 104 or even prevent its formation entirely.

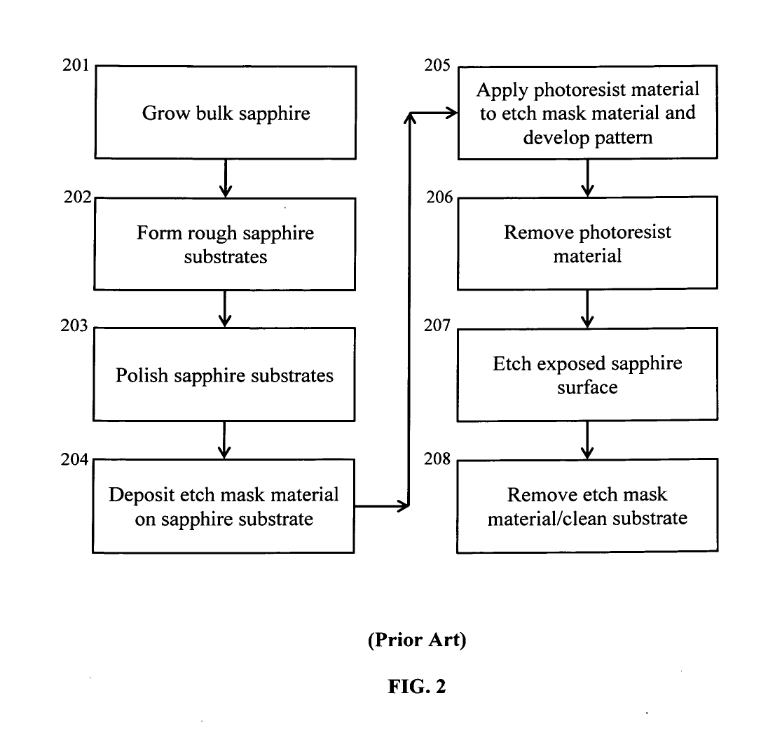

Prior art methods of forming a patterned sapphire substrate are illustrated in FIG. 2. The first step in the process is growth of a bulk sapphire crystal 201. Next the bulk sapphire crystal is formed into rough substrates 202 that approximate the shape of a finished sapphire substrate. In the next step the rough substrates are lapped to the appropriate thickness and polished 203 to produce a surface suitable for epitaxial growth.

These finished sapphire substrates are then coated with a mask material 204 over the growth surface. Photolithographic methods are then used to define and etch portions of the mask material and expose portions of the sapphire surface 205. This is a multi-step process that involves deposing a photoresist material, exposing the photoresist using a mask, developing the photoresist to expose portions of the mask material and then etching the mask material. In some cases the remaining photoresist material may be stripped 206 before the next step. In some processes this step is not required.

After forming the patterned mask, the sapphire substrate is then subjected to an etch process 207. The high hardness and low chemical reactivity of sapphire present issues to etch processes. Plasma etch based processes based on reactive halogen chemistries are commonly used. The capital equipment for such processes is high due to safety requirements.

Further due to stringent process control requirements to produce a uniform sapphire etch, only a limited number of substrates may be processed in a batch. This requirement significantly increases process time and hence cost.

Wet chemistries are known that are capable of etching sapphire, but these are based on highly concentrated acids at temperature around about 250° C. to about 300° C. The extreme reactivity of concentrated acids at this temperature poses significant safety issues and hence remains a costly option.

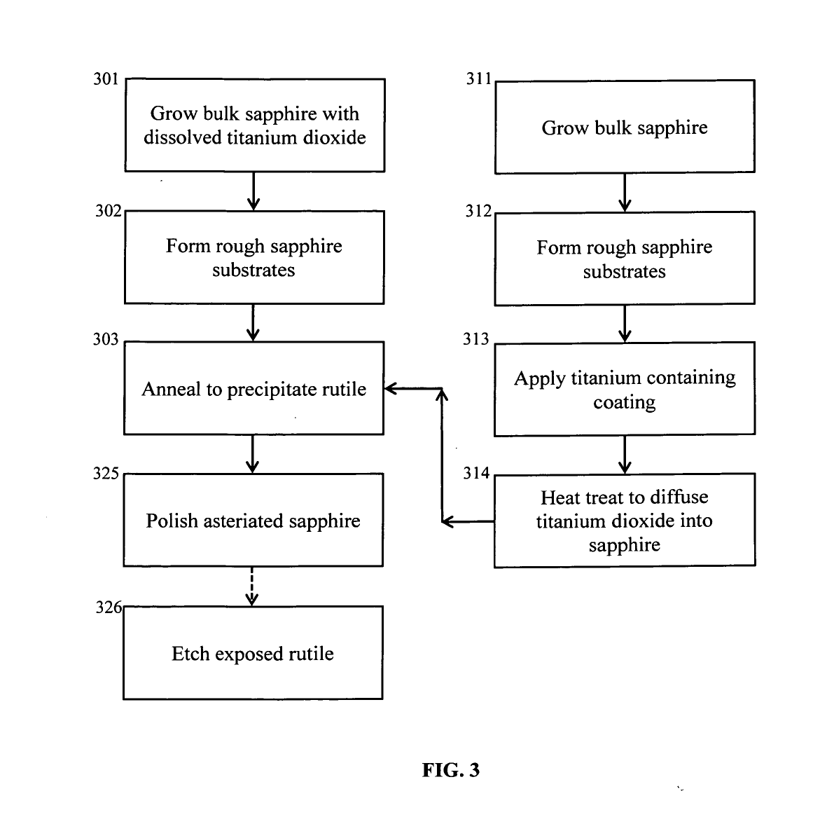

One embodiment of the present invention is a sapphire substrate with rutile inclusions capable of acting as optical scattering centers. Two representative process flow diagrams are illustrated in FIG. 3. The first representative process flow begins with growth of a bulk sapphire substrate containing dissolved titanium dioxide 301. Dissolved titanium dioxide concentrations in the bulk sapphire are preferably between about 0.01% to about 0.5%. Below about 0.01% it may not be possible to precipitate rutile in the sapphire. At concentrations above about 0.5% the bulk sapphire may acquire a distinct body color that may result in unfavorable optical properties in the final substrate.

In the next process step the bulk sapphire with dissolved titanium dioxide is formed into rough substrates 302 using means known in the art. The rough substrates are then annealed at a temperature between about 1100° C. and about 1500° C. for a time between about 30 minutes and about 12 hours 303 to cause the precipitation of rutile inclusions in the sapphire. At higher temperatures the precipitations occurs more rapidly and the annealing time may be shorter. Below about 1100° C. rutile will either fail to precipitate or require an unacceptably long time to do so. Above about 1500° C. the rutile will also fail to precipitate. This occurs because the solubility of titanium dioxide in sapphire increases with temperature. Thus at higher temperatures the dissolved titanium dioxide may be stable and there will be no thermodynamic drive for it to precipitate.

In the next process step the rough sapphire with rutile inclusions is polished to form a finished substrate 325. In this form the substrate may have rutile inclusions that extend to the surface of the sapphire substrate. If desired a wet chemical etch step may be used 326 to form a patterned sapphire substrate with rutile inclusions.

Alternatively this process may begin with rough sapphire substrates without significant dissolved titanium dioxide as in the prior art process represented in FIG. 2. The first two steps in the process 311, 312 proceeds as before up to the point that rough sapphire substrates are formed 312.

In the next process step the rough sapphire substrates are coated with a titanium containing material 313. This material may take one of a number of forms as outlined elsewhere in the present application. The coated substrate is then subject to a heat treatment step 314 to diffuse titanium dioxide into the body of the substrate. This diffusion step 314 is preferably conducted at a temperature between about 1600° C. and about 1950° C. for a time between about 30 minutes and about 24 hours.

The choice of temperature and time for the diffusion heat treatment depends on the desired depth of penetration. At higher temperatures the titanium dioxide will diffuse faster into the rough sapphire. The depth of diffusion also increases with time.

At this point a rough sapphire substrate with dissolved titanium dioxide has been formed and the process flow continues as outlined above through process steps 303, 325 and optionally to 326.

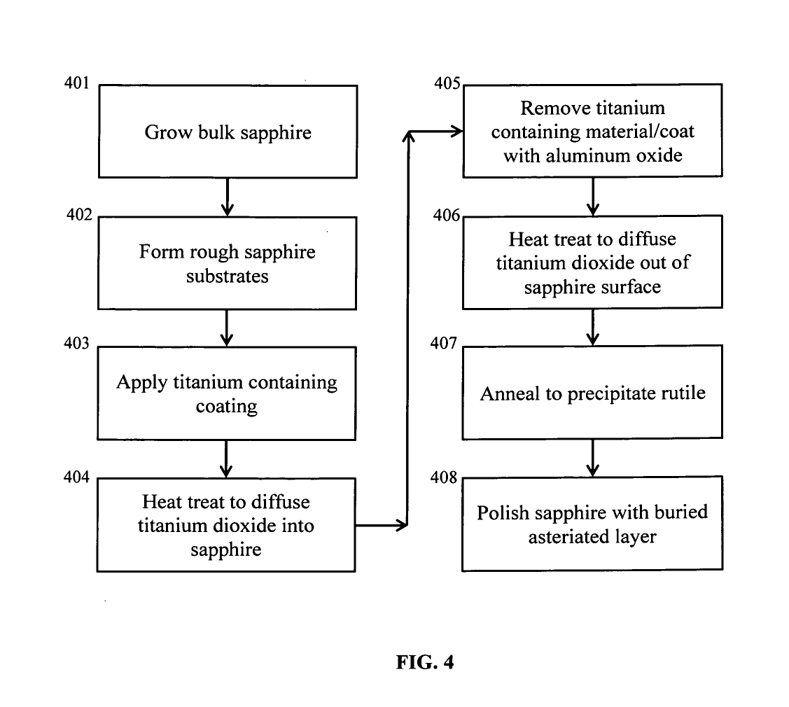

The process flow for another embodiment of the present invention is outlined in FIG. 4. The process incorporates process steps included in previous process flow diagrams and is briefly summed up by: 1) growth of bulk sapphire 401, formation of rough sapphire substrates 402, applying a coating of a titanium containing material 403, followed by heat treatment to diffuse titanium dioxide into the sapphire 404.

In the next process step the coating of titanium containing material is removed 405. This is followed by coating the sapphire with a material comprising aluminum oxide and reheating the sapphire to a temperature between about 1600° C. and about 1950° C. 406. It is important that the coating material not comprise any materials containing titanium.

During this process step titanium dioxide diffuses back out of the sapphire and into the coating material. This results in depletion of titanium dioxide from the surface region of the sapphire.

In the next process step the rough substrate is annealed at a temperature between about 1100° C. and about 1500° C. to cause dissolved titanium dioxide to precipitate as rutile 407. Since the surface region was depleted of titanium dioxide in the previous process step 406 the rutile will only precipitate below the surface of the sapphire.

The final process step is polishing of the rough sapphire substrate to form a polished sapphire substrate 408 suitable for use in epitaxial growth.

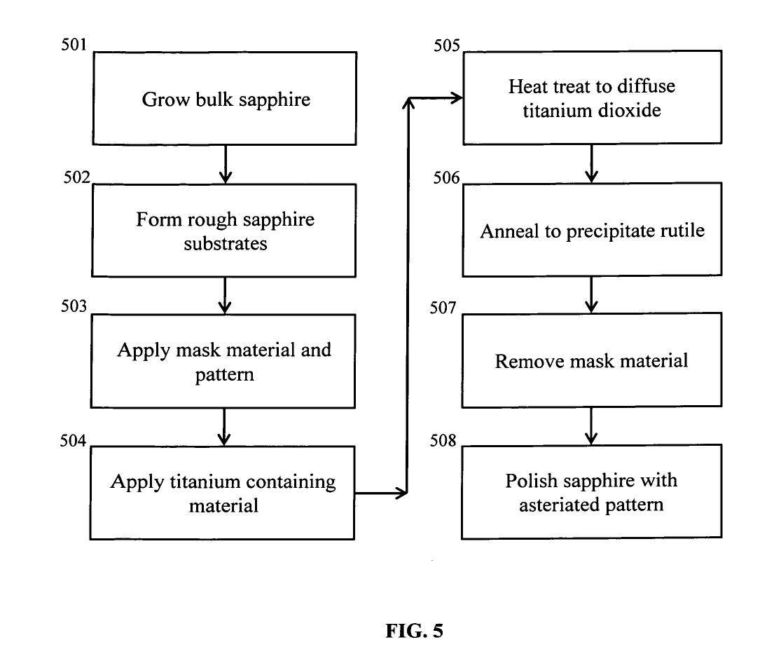

FIG. 5 outlines a modified process for producing an asteriated sapphire substrate in which the rutile precipitates in selected regions of the substrate. The first two process steps mimic prior art processes for forming sapphire substrates and include growth of a bulk sapphire substrate 501 followed by forming the bulk sapphire crystal into rough sapphire substrates 502.

In the next process step a mask material is applied to the surface of the rough substrate 503. The mask should comprise a material that is capable of acting as a diffusion barrier to titanium and titanium dioxide. This mask material is then patterned using photolithographic methods known in the art 503 to expose portions of the rough sapphire surface

The rough sapphire substrate with a patterned mask is then coated with a titanium containing material 504 and subject to a diffusion heat treatment to diffuse titanium dioxide into the sapphire 505. As noted previously this diffusion heat treatment preferably occurs at a temperature between about 1600° C. and about 1950° C. for a time between about 30 minutes and about 24 hours.

Due to the presence of the diffusion barrier or mask material on selected portions of the sapphire surface, titanium dioxide only diffuses into the sapphire surface that is exposed and in contact with the titanium dioxide containing material.

In the next process step that rough sapphire wafer is annealed at a temperature between about 1100° C. and about 1500° C. for a time period of about 30 minutes and about 12 hours 506 to cause the precipitation of rutile. The rough substrate is then cooled (not shown) and the mask material is removed 507. In the final process step the rough substrate with selected areas of rutile inclusions is polished to for a sapphire substrate.

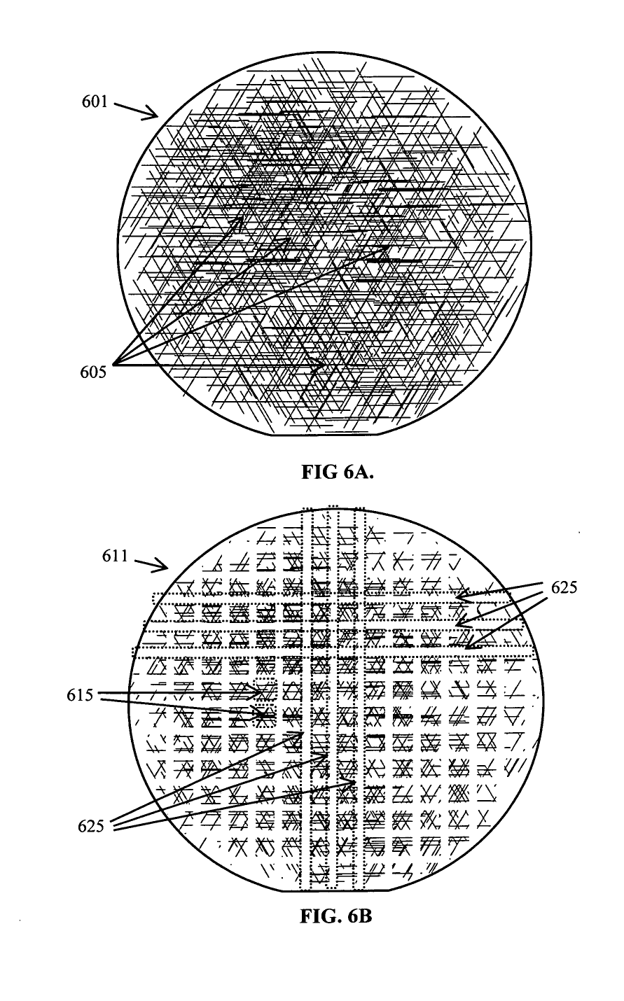

FIGS. 6A and 6B illustrate representative plan views of sapphire substrates with rutile inclusions according to embodiments of the present invention. In FIG. 6A the sapphire substrate 601 contains a uniform distribution of rutile inclusions 605. The density of rutile inclusions is influenced by the amount of titanium dioxide dissolved in the sapphire prior to the precipitation annealing step.

FIG. 6B illustrates a sapphire substrate 611 with a pattern of regions containing rutile inclusions 615 and regions free of rutile inclusions 625.

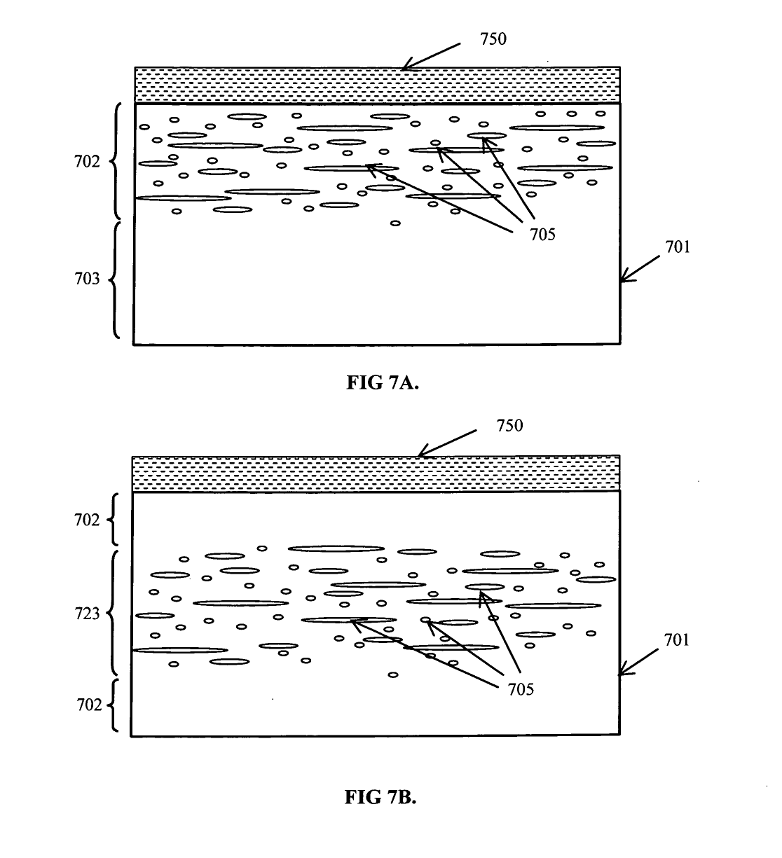

FIGS. 7A and 7B illustrate representative cross sectional views of sapphire substrates according to embodiments of the present invention. FIG. 7A shows a sapphire substrate 701 with a layer of sapphire containing rutile inclusions 702. The rutile inclusions 705 in this layer 702 extend to the surface of the sapphire substrate 701. The portion of the substrate far from the growth surface comprises a layer of sapphire that is substantially free of rutile inclusions 703. A representative GaN epitaxial layer 750 is shown on the top surface of the substrate.

FIG. 7B illustrates a sapphire substrate 701 with a layer of sapphire containing rutile inclusions 723. In this embodiment the rutile inclusions 705 do not extend to the surface of the sapphire substrate 701. Instead a layer of sapphire substantially free of rutile inclusions 702 is present both above and below the layer of sapphire with rutile inclusions 723. A representative GaN epitaxial layer 750 is shown for reference.

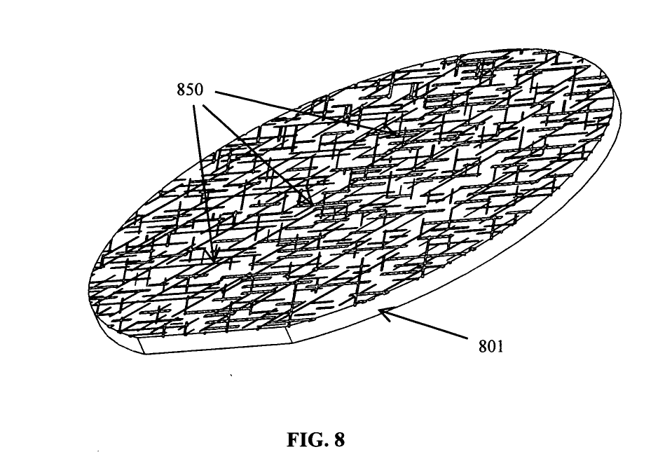

FIG. 8 illustrates a representative isometric view of one embodiment of the present invention. In this embodiment a sapphire substrate 801 was processed using methods outlined above that resulted in formation of rutile inclusions (not shown) that penetrated to the surface of the sapphire substrate 801. The exposed rutile inclusions were subject to an etch process and removed. This step leaves a patterned sapphire surface 850 wherein the recessed portions of the patterned sapphire surface 850 represent the locations of exposed rutile inclusions that were removed by etching.

### DESCRIPTION OF THE INVENTION

The present invention comprises an asterated sapphire substrate for growth of a GaN based light emitting diode. In one embodiment of the invention, bulk sapphire is grown with a titanium dioxide in a solid solution with a concentration of about 0.01% to about 0.5%. This bulk sapphire with dissolved titanium dioxide is then processed to rough substrate form. Prior to final polishing, these rough substrates are heated to a temperature between about 1100° C. and about 1500° C. for a period of about 30 minutes to about twelve hours to cause titanium dioxide to precipitate in the form of rutile needles. Shorter times are required for rutile precipitate at higher temperatures.

During this annealing step the dissolved titanium dioxide precipitates in the form of needle like inclusions of rutile. These rutile needles are preferentially oriented along the sapphire (1120) crystal planes and are oriented at 120° degrees from each other. The rutile needles are also dispersed throughout the volume of the sapphire and thus form a three dimensional network of optical scattering centers.

After this step the substrates may be polished using methods known in the art. If desired exposed rutile may be etched using any of a variety of etching solutions known in the art. Due to the extreme differences in hardness and chemical reactivity, the rutile is readily etched in a wet chemical bath at or near room temperature without damage to the sapphire matrix. Dry or plasma based etches may also be used to preferentially etch exposed rutile, but are not generally preferred due to longer net processing times and higher unit cost.

Etching exposed rutile leaves a textured or patterned sapphire surface that will be optically similar to patterned sapphire surfaces produced using photolithography and plasma etch methods. A crucial difference is that etching rutile can be effectively performance on a large batch of substrates as opposed the known methods for producing patterned sapphire substrates.

In another embodiment of the invention rough sapphire substrates are formed from bulk sapphire with no appreciable concentration of titanium dioxide. A finely powdered mixture of aluminum and titanium dioxide with about 10% to 100% titanium dioxide is applied to the rough substrate surface. The coated substrate is then heated to a temperature of about 1600° C. to about 1950° C. for a period of about 30 minutes to about 24 hours. The rough substrates are then cooled and may be processed through final polishing. In some cases it may also be desirable to maintain the rough substrates at a temperature between about 1100° C. and about 1500° C. during cooling for a period of about 30 minutes to about twelve hours during the cooling process.

In another embodiment of the invention the rough sapphire substrates are formed from bulk sapphire with no appreciable concentration of titanium dioxide. These rough substrates are coated with a film of titanium dioxide using a sputtering or other physical deposition process. Other processes known in the art may also be used to deposit the film of titanium dioxide. The coated substrate is then heated to a temperature of about 1600° C. to about 1950° C. for a period of about 30 minutes to about 24 hours. The rough substrates are then cooled and may be processed through final polishing. In some cases it may also be desirable to maintain the rough substrates at a temperature between about 1100° C. and about 1500° C. for a period of about 30 minutes to about twelve hours during the cooling process.

In another embodiment of the invention the rough sapphire substrates from bulk sapphire with no appreciable concentration of titanium dioxide may be coated with titanium metal or another titanium containing material deposited using a sputtering, evaporation or other physical deposition process. The coated substrate is then heated to a temperature of about 1600° C. to about 1950° C. for a period of about 30 minutes to about 24 hours in an oxidizing atmosphere. The rough substrates are then cooled and may be processed through final polishing. In some cases it may also be desirable to maintain the rough substrates at a temperature between about 1100° C. and about 1500° C. for a period of about 30 minutes to about twelve hours during the cooling process.

Each heating process has a distinct purpose. The high temperature step allows titanium dioxide to diffuse from the surface into the body of the substrate. Higher temperatures allow for more rapid diffusion and can result in a net higher concentration of titanium dioxide in sapphire. The lower temperature process allows the dissolved titanium dioxide to precipitate and form rutile inclusions. This process is driven by the fact that high temperatures increase the solubility of titanium dioxide in sapphire. If the temperature is decreased rapidly below about 1100° C., then the titanium dioxide will stay in a solid solution. Maintaining the temperature at an intermediate temperature between about 1100° C. and about 1500° C. for an extended period of time to allow dissolved titanium dioxide to precipitate as rutile.

In the case of rough substrates coated with titanium, it is important to conduct the high temperature diffusion step in an oxidizing ambient. In a non-oxidizing ambient titanium will diffuse into sapphire, but it will also introduce oxygen vacancies which may have a detrimental impact on the suitability of the sapphire as a substrate for epitaxial growth. An oxidizing ambient helps to convert titanium to titanium dioxide. An oxidizing ambient also helps to suppress any oxygen vacancies that may be introduced by titanium diffusion.

Increasing the length of time the sapphire and titanium dioxide or titanium containing material is held at high temperature increases the depth that titanium dioxide diffuses into the sapphire. The diffusion time can be extended beyond the times discussed above. At sufficiently long times titanium dioxide can be diffused throughout the entire rough sapphire substrate. However since one of the final processing steps of GaN LEDs prior to separation into individual LED chips is to thin the sapphire substrate to a thickness of about 100 μm, it is rarely necessary to diffuse titanium dioxide to deeper depths.

In another embodiment of the invention the rough sapphire substrates are cooled below about 1100° C. after the diffusion step without an annealing step. The titanium dioxide or titanium is then removed and the rough substrates are coated with a finely powdered material containing aluminum dioxide. The rough substrate is then reheated to a temperature of about 1600° C. to about 1950° C. for about 30 minutes to about 24 hours. The rough substrate is then cooled to about 1100° C. to about 1500° C. for an extended period of time to allow dissolved titanium dioxide to precipitate as rutile.

By conducting a second diffusion step without titanium dioxide or other titanium containing material present of the sapphire surface titanium dioxide diffuses out of the rough sapphire substrate and into the surrounding material. This leaves the surface layer of the rough sapphire substrate depleted in titanium dioxide. The level of dissolved titanium dioxide adjacent to the surface can be reduced to a level below the level that will allow rutile precipitation during the subsequent annealing step.

In this manner it is possible to form a sapphire substrate with a buried layer of rutile inclusions and no precipitated rutile at the surface of the substrate that will later be used for epitaxial growth.

Variations in the processing may also include coating the substrate on only one side or using a coating with different concentrations of titanium materials on each side of the rough substrate.

In another embodiment a photolithography process is used to pattern a rough sapphire substrate containing no appreciable amounts of dissolved titanium dioxide. This rough substrate is then coated with a titanium containing material and annealed at a temperature between about 1600° C. and about 1950° C. for about 30 minutes to about 24 hours. The temperature of the rough substrate is then lowered to about 1100° C. to about 1500° C. for an extended period of time to allow dissolved titanium dioxide to precipitate as rutile.

The rough sapphire substrate is then cooled and processed and polished to for a sapphire substrate suitable for epitaxial growth of GaN materials.

The presence of the mask material on the sapphire during the high temperature diffusion step acts as a barrier to titanium dioxide diffusion. As a result the no rutile will precipitate in the sapphire under the mask material. In this manner it is possible to for a sapphire substrate with regions of rutile inclusions and regions without rutile inclusions.

At this point of the processes outlined above the rough substrates go through final polishing steps to produce a surface suitable for epitaxial growth. In cases where the rutile inclusions extend to the surface for epitaxial growth this would leave a surface comprised of regions of crystalline sapphire and rutile. Due to differences in the chemical reactivity of sapphire and rutile and also the difference in lattice constants it may be possible to adjust the growth conditions to result in selective growth on one material or the other. If deposition can be eliminated or suppressed on the rutile material then epitaxial growth of GaN materials in the lateral direction would not be constrained by the lattice constant of the rutile. This would greatly reduce the dislocation density of the GaN materials over the rutile. This would lower the overall dislocation density of the resulting epitaxial layer and allow growth of higher quality material.

In some embodiments where the final polished substrate surface includes regions of both sapphire and rutile, the growth surface may be subjected to a chemical etching step prior to epitaxial growth of GaN based materials. This may be accomplished using wet chemical etching solutions that preferentially etch exposed rutile. Such etching solutions include but are not limited to: HCl, H₂SO₄, H₂O₂:HNO₃, H₂O₂:NH₃. In this manner the exposed rutile is preferentially removed and a textured sapphire surface is formed.

In this manner a patterned sapphire surface for epitaxial growth can be formed using a simple wet chemical etch process. This step can be performed as a bulk process on dozens of substrates at a single time.

In another embodiment the backside of the sapphire substrate with exposed rutile inclusions is exposed to a solution that preferentially etches rutile after formation of LED devices. This forms patterns on the backside of the substrate that can further improve optical performance. In some embodiments this patterned backside may be coated with a reflective material to improve light extraction through the GaN layer of the LED device. In other embodiments the LED device is formed as a flip chip device and light is extracted through the patterned sapphire surface opposite the GaN layers.

The above described embodiments allow formation of high quality sapphire substrates with optical scattering zones without the need to use high power lasers which results in a dramatic reduction in cost. Further embodiments of the present invention allow the formation of patterned sapphire substrates without the need to use expensive semiconductor fabrication equipment. Embodiments also avoid use of plasma based etching of sapphire to form a patterned sapphire substrate. Crucially embodiments of the present invention allow the formation of both scattering centers and patterned sapphire surfaces using a simple and inexpensive process.

While the invention has been described in detail in connection with only a limited number of embodiments, it should be readily understood that the invention is not limited to such disclosed embodiments, rather, the invention can be modified to incorporate any variations, alterations, substitutions or equivalent arrangements not heretofore described, but are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed:

1. A substrate with a first major surface and a second major surface for epitaxial growth of GaN materials comprising a crystalline sapphire material with oriented titanium dioxide inclusions

2. A substrate of claim 1 wherein said oriented titanium dioxide inclusions form a layer parallel to the first major surface and the second major surface

3. A substrate of claim 1 wherein said oriented titanium dioxide inclusions form a layer that extends to at least one major surface of said substrate

4. A substrate of claim 1 wherein said oriented titanium dioxide inclusions extends to neither said first major surface nor to said second surface

5. A substrate with a first major surface and a second major surface for epitaxial growth GaN materials comprising a crystalline sapphire material with oriented titanium dioxide inclusions wherein said oriented titanium dioxide inclusions are exposed on at least one major surface

6. A substrate of claim 5 wherein said exposed titanium dioxide inclusions are chemically etched prior to epitaxial growth of GaN materials

7. A method of forming a substrate according to claim 1 comprising:
Growing a bulk sapphire crystal
Cutting said sapphire material into a rod shape along an axis nominally suitable for epitaxial growth of GaN materials
Slicing said sapphire rod into thin slices to form rough sapphire substrates with a first major surface and a second major surface
Coating at least one said major surface with a titanium containing material
Annealing said rough substrate with said coating of titanium containing material to a temperature between about 1600° C. and about 1950° C. for a period of about 30 minutes to about 24 hours after which the temperature of said rough substrate is reduced
Holding said rough sapphire substrates at a temperature between about 1100° C. and about 1500° C. for a period of about 30 minutes to about 12 hours after which said rough substrate is allowed to cool
Polishing at least one major surface of said rough sapphire substrates with rutile inclusions to form a surface suitable for epitaxial growth of GaN materials

8. A method of forming a substrate according to claim 1 comprising:
Growing a bulk sapphire crystal
Cutting said sapphire material into a rod shape along an axis nominally suitable for epitaxial growth of GaN materials
Slicing said sapphire rod into thin slices to form rough sapphire substrates with a first major surface and a second major surface
Coating at least one said major surface with a titanium containing material
Annealing said rough substrate with said coating of titanium containing material to a temperature between about 1600° C. and about 1950° C. for a period of about 30 minutes to about 24 hours after which the temperature of said rough substrate is allowed to cool
Coating said major surface previously coated with a titanium containing material with a powdered material containing aluminum oxide
Heating said rough substrate a second time to a temperature between about 1600° C. and about 1950° C. for a period of about 15 minutes to about 10 hours after which the rough substrate is allowed to cool
Holding said rough sapphire substrates at a temperature between about 1100° C. and about 1500° C. for a period of about 30 minutes to about 12 hours after which said rough substrate is allowed to cool
Polishing at least one major surface of said rough sapphire substrates with rutile inclusions to form a surface suitable for epitaxial growth of GaN materials wherein said polished sapphire surface is free of rutile inclusions

9. A method of forming a substrate according to claim 1 comprising:
Growing a bulk sapphire crystal containing between 0.01% and 0.5% dissolved titanium dioxide
Cutting said sapphire material into a rod shape along an axis nominally suitable for epitaxial growth of GaN materials
Slicing said sapphire rod into thin slices to form rough sapphire substrates with a first major surface and a second major surface
Heating said rough sapphire substrates to a temperature between about 1100° C. and about 1500° C. for a time adequate to allow said dissolved titanium dioxide to precipitate in the form of rutile inclusions
Polishing at least one major surface of said rough sapphire substrates with rutile inclusions to form a surface suitable for epitaxial growth of GaN materials

10. A method for forming a substrate according to claim 1 comprising:
Growing a bulk sapphire crystal
Cutting said sapphire material into a rod shape along an axis nominally suitable for epitaxial growth of GaN materials
Slicing said sapphire rod into thin slices to form rough sapphire substrates with a first major surface and a second major surface
Coating at least one said major material with a mask material that does not contain titanium and is capable of acting as a barrier to diffusion of titanium and titanium dioxide at high temperatures
Forming holes in said mask material to expose regions of sapphire on said coated major surface
Coating said major surface with said mask material and exposed regions of sapphire with a titanium containing material
Annealing said rough substrate with said mask material and exposed regions of sapphire and said coating of titanium containing material to a temperature between about 1600° C. and about 1950° C. for a period of about 30 minutes to about 24 hours after which the temperature of said rough substrate is allowed to decrease
Holding the temperature of said rough substrate at a temperature between about 1600° C. and about 1950° C. for a period of about 15 minutes to about 10 hours after which the rough substrate is allowed to cool
Polishing at said major surface of said rough sapphire substrates previously coated with said patterned mask material to form a surface suitable for epitaxial growth of GaN materials wherein said substrate contains regions with rutile inclusions and regions free of rutile inclusions
